(19) United States
(12) Patent Application Publication
(10) Pub. No.: US 2024/0417586 A1
(43) Pub. Date: Dec. 19, 2024

(54) CURABLE RESIN COMPOSITION AND PROCESS FOR PRODUCING PRINTED WIRING BOARD USING THE SAME

(71) Applicant: TAIYO HOLDINGS CO., LTD., SAITAMA-KEN (JP)

(72) Inventors: Yasuyo KANAZAWA, SAITAMA-KEN (JP); Tomotaka NOGUCHI, SAITAMA-KEN (JP); Takuto TAMURA, SAITAMA-KEN (JP); Fumiko KOMATSU, SAITAMA-KEN (JP)

(73) Assignee: TAIYO HOLDINGS CO., LTD., SAITAMA-KEN (JP)

(21) Appl. No.: 18/621,214

(22) Filed: Mar. 29, 2024

(30) Foreign Application Priority Data
Mar. 31, 2023 (JP) 2023-058588

(51) Int. Cl. C09D 163/00; C08K 3/013; H05K 3/26; H05K 3/40

(52) U.S. Cl. CPC C09D 163/00; H05K 3/26; H05K 3/4038; C08K 3/013; C08K 2201/003; C08K 2201/01

(57) ABSTRACT

Provided is a curable resin composition that can be smoothed by polishing after being filled into a through-hole and inhibits a recess from being generated in the through-hole. The curable resin composition comprises a curable resin, a curing agent, and an inorganic filler. A printed wiring board, in which the through-holes are filled with the cured product of the curable resin composition, has a specific cured product-coating regions.

### BACKGROUND OF THE INVENTION

### Field of the Invention

The present invention relates to a curable resin composition, more specifically a curable resin composition that can be preferably used as a filler for filling through-bores such as through-holes in a printed wiring board, and to a method of producing a printed wiring board using the curable resin composition.

### DESCRIPTION OF THE RELATED ART

With the downsizing and more functionality of electronic instruments, the finer patterns of printed wiring boards, reductions in mounting areas, and the higher densities of mounting of components have been demanded. Therefore, multilayered substrates such as a double-sided substrate provided with through-bores that form interlayer connection for electrically connecting different wiring layers to each other, that is, through-holes, and a buildup wiring board multilayered by sequentially forming an insulation layer and a conductor circuit are on a core material and performing interlayer connection thereof through via holes and the like have been used.

In such a printed wiring board, recesses between conductor circuits on a surface, and holes such as through-holes and via holes on the inner wall surfaces of which wiring layers are formed are commonly subjected to filling processing treatment with a thermosetting resin composition. A curable resin composition containing an epoxy resin as a curable resin component, an epoxy resin curing agent, and an inorganic filler is commonly used as such a thermosetting resin composition. In the filling processing treatment, the curable resin composition is filled into holes in a substrate by means such as screen printing, the curable resin composition is cured, and a surplus cured product is polished to smooth the substrate.

In recent years, curable resin compositions have been increasingly required to be excellent in filling properties with reductions in the diameters of through-holes and via holes, and, for example, filling properties have been known to be able to be improved by blending specific inorganic fillers into curable resin compositions (for example, Japanese Patent Application No. 2007-235121, Japanese Patent Application No. 2017-71656, and the like).

### SUMMARY OF THE INVENTION

In the case of such a curable resin composition excellent in filling properties as described above, the curable resin composition discharged from a through-hole opening in the other surface side of the printed wiring board has spread out while offering moistness when the curable resin composition has been filled from one surface of a printed wiring board into a through-bore such as a through-hole by printing means. Thus, polishing of a surplus portion after curing of the curable resin composition has been able to result in generation of a recess without completely filling the through-hole.

Accordingly, an objective of the present invention is to provide a curable resin composition that can be smoothed by polishing after being filled into a through-hole and inhibits a recess from being generated in the through-hole.

The present inventors found that even when a curable resin composition spread, while offering moistness, from a through-hole opening in a surface reverse to the printing surface of a printed wiring board, the curable resin composition can be smoothed in a subsequent polishing step depending on the manner of the spreading. The present inventors further advanced examination and found that the shape of the curable resin composition spreading while offering the moistness affects smoothness after the polishing. The present invention is based on such findings. In other words, the gist of the present invention is as follows.

[1] A curable resin composition including a curable resin, a curing agent, and an inorganic filler, wherein
when the curable resin composition is filled from one principal surface side of a printed wiring board having a thickness of 1.6 mm, in which a plurality of through-holes including a wall surface subjected to plating treatment and having an inner diameter of 0.12 mm and a generally columnar shape are evenly spaced 1 mm apart in a substrate including a surface subjected to plating treatment and having a total thickness of 1.6 mm, into the through-holes, followed by curing the curable resin composition,
in a case in which a principal surface reverse to the principal surface side from which the curable resin composition is filled, of principal surfaces of the printed wiring board, is viewed from a front, the principal surface includes cured product-coating regions in which the principal surface of the substrate is coated with a cured product of the curable resin composition to cover a periphery of each of the through-holes, and
when a linear longest distance of each of the cured product-coating regions is r_{L} (μm), and a linear longest distance of a line segment orthogonal to the line segment of the r_{L} at a center of the line segment of r_{L} is r_{S} (μm),
cured product-coating regions satisfying

$$1 \leq {r}_{L} / {r}_{S} \leq 1.5$$

are 50% or more of all the cured product-coating regions.

[2] The curable resin composition according to [1], wherein the inorganic filler is included at a ratio of 40 to 90% by mass with respect to a total solid content of the curable resin composition.

[3] The curable resin composition according to [1] or [2], wherein an average particle diameter of the inorganic filler is 0.1 to 20 μm.

[4] The curable resin composition according to any one of [1] to [3], wherein the inorganic filler includes a magnetic filler.

[5] A method of producing a printed wiring board using the curable resin composition according to any one of [1] to [4], the method including:
preparing a printed wiring board in which a plurality of through-holes having a generally columnar shape are disposed;
filling the curable resin composition from one principal surface side of the printed wiring board into the through-holes by printing; and
curing the filled curable resin composition,
wherein
when the curable resin composition is filled, the curable resin composition is discharged from through-holes in a principal surface reverse to the printed side, of principal surfaces of the printed wiring board, and an amount of the filled curable resin composition is adjusted to prevent curable resin compositions discharged from through-holes adjacent to each other from coming into contact with each other.

[6] The method according to [5], further including polishing the principal surface reverse to the printed side, of the principal surfaces of the printed wiring board, after curing of the filled curable resin composition.

In accordance with the present invention, there can be provided a curable resin composition that can be smoothed by polishing after being filled into a through-hole and inhibits a recess from being generated in the through-hole.

### BRIEF DESCRIPTION OF THE DRAWINGS

FIG. 1A is a schematic view for explaining a step of producing a printed wiring board that is filled with a curable resin composition of the present invention;

FIG. 1B is a schematic view for explaining the step of producing the printed wiring board that is filled with the curable resin composition of the present invention;

FIG. 1C is a schematic view for explaining the step of producing the printed wiring board that is filled with the curable resin composition of the present invention;

FIG. 1D is a schematic view for explaining the step of producing the printed wiring board that is filled with the curable resin composition of the present invention;

FIG. 2 is a front view of a principal surface reverse to the printing side of a printed wiring board in the state of curing a curable resin composition filled into each through-hole in the printed wiring board in which a plurality of through-holes are opened at regular spacings;

FIG. 3 is a cross-sectional view taken along the line X-X′ line of FIG. 2;

FIG. 4 is an enlarged view of any one of through-holes illustrated in FIG. 3 (in the case of 1≤r_{L}r_{S}≤1.5); and

FIG. 5 is an enlarged view of any one of through-holes illustrated in FIG. 3 (in the case of r_{L}/r_{S}≥1.5).

### DETAILED DESCRIPTION OF THE INVENTION

### <Curable Resin Composition>

A curable resin composition of the present invention includes a curable resin, a curing agent, and an inorganic filler as essential components. In the present invention, the curable resin composition is provided in which when the curable resin composition is filled from one principal surface side of a printed wiring board having a thickness of 1.6 mm, in which a plurality of through-holes including a wall surface subjected to plating treatment and having an inner diameter of 0.12 mm and a generally columnar shape are evenly spaced 1 mm apart in a substrate including a surface subjected to plating treatment and having a total thickness of 1.6 mm, into the through-holes, followed by curing the curable resin composition,
in a case in which a principal surface reverse to the principal surface side from which the curable resin composition is filled, of principal surfaces of the printed wiring board, is viewed from a front, and the principal surface includes the cured product-coating regions in which the principal surface of the substrate is coated with a cured product of the curable resin composition to cover a periphery of each of the through-holes, and
when a linear longest distance of each of the cured product-coating regions is r_{L}(μm), and a linear longest distance of a line segment orthogonal to the line segment of the r_{L} at a center of the line segment of r_{L} is r_{S}(μm), cured product-coating regions satisfying

$$1 \leq {r}_{L} / {r}_{S} \leq 1.5$$

are 50% or more of all the cured product-coating regions, whereby the printed wiring board in which the through-holes are filled with the cured product of the curable resin composition, and which includes a smooth surface including no recess after polishing of the surface can be obtained.

The present invention is described in detail below with reference to the drawings.

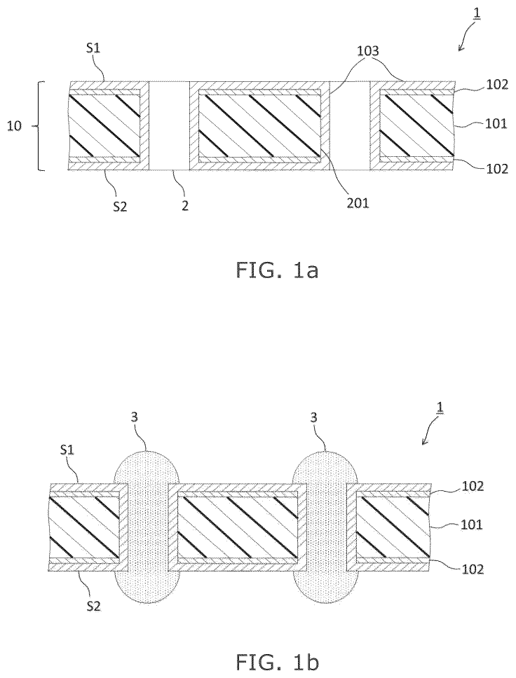

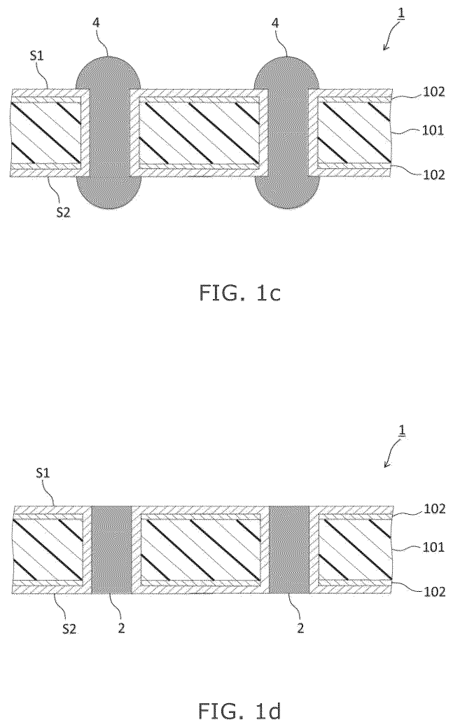

FIGS. 1A to 1D are schematic views for explaining a step of filling through-holes in a printed wiring board using the curable resin composition. First, a printed wiring board 1 including through-holes 2 is prepared (FIG. 1A). In the printed wiring board 1, copper foils (wiring layers) 102 are disposed on both surfaces of an insulation layer 101, the through-holes 2 are formed in a surface of a substrate by a drill or the like, and the inner walls 201 of the through-holes 2 and the surfaces of the wiring layers 102 were subjected to plating treatment to form plated layers 103.

A glass epoxy substrate, a polyimide substrate, a resin substrate such as a bismaleimide-triazine resin substrate or a fluorine resin substrate, or a copper-clad laminate of such a resin substrate, a ceramic substrate, a metal substrate, or the like can be used as the insulation layer 101.

The copper foils 102 are disposed on both the surfaces of the insulation layer 101. Each of the copper foils 102 has a thickness of 18 μm. The surfaces of the copper foils 102 are preferably subjected to buffing-polishing and the like, and then to acid washing.

In the plating treatment, electroless plating and electrolytic plating are performed for a thick coating to form the plated layers 103 on the surfaces of a substrate 10. The thickness of each plated layer 103 is 30 μm. Copper plating is preferred as such electroless plating and electrolytic plating. A conventionally known method can be preferably applied to the method of the electroless plating or the electrolytic plating.

The total thickness of the printed wiring board 1, that is, the thickness including the thicknesses of the insulation layer 101, the wiring layers 102, and the plated layers 103 is 1.6 mm, and the through-holes 2 are disposed perpendicularly to a principal surface of the printed wiring board 1. Each through-hole 2 includes the inner wall 201 subjected to the plating treatment, and has a generally columnar shape having an inner diameter of 0.12 mm. The plurality of through-holes 2 having the shapes described above are evenly spaced 1 mm apart in the printed wiring board 1.

Then, a curable resin composition 3 is filled from one principal surface S1 side of the printed wiring board into the through-holes 2 by printing (FIG. 1B). In such a case, the amount of the curable resin composition 3 filled in the printing is adjusted so that the curable resin composition is discharged from the through-holes closer to the principal surface S2 (hereinafter may also be referred to as “discharge surface”) reverse to the principal surface S1 (hereinafter may also be referred to as “printing surface”) of the principal surfaces S1 and S2 of the printed wiring board 1 to form swellings 4. Specifically, the curable resin composition 3 is discharged from the through-holes 2, closer to the discharge surface S2, of the printed wiring board 1, and the amount of the filled curable resin composition is adjusted to prevent curable resin compositions discharged from through-holes adjacent to each other from coming into contact with each other. More specifically, the curable resin composition is filled into the through-holes the amount of the injected curable resin composition is 0.04±0.01 mm³ per through-hole.

Then, the printed wiring board 1 is heated at a predetermined temperature for predetermined time to cure the filled curable resin composition (FIG. 1C). The curing is not limited at all; however, in the present invention, the printed wiring board 1 filled with the curable resin composition 3 is mounted so that a principal surface of the board is at an angle of 90°±10° with respect to a mounting surface, and the temperature of the printed wiring board 1 is increased from ordinary temperature to 130° C. for 10 minutes, kept at 130° C. for 45 minutes, then increased from 130° C. to 150° C. for 10 minutes, and kept at 150° C. for 60 minutes to cure the filled curable resin composition 3.

Subsequently, the unwanted portions of the swellings 4 protruding from the through-holes 2, closer to the printing surface S1 and the discharge surface S2, of the printed wiring board 1 are removed and flattened by polishing (FIG. 1D). The polishing can be preferably performed by a belt sander, buffing-polishing, or the like.

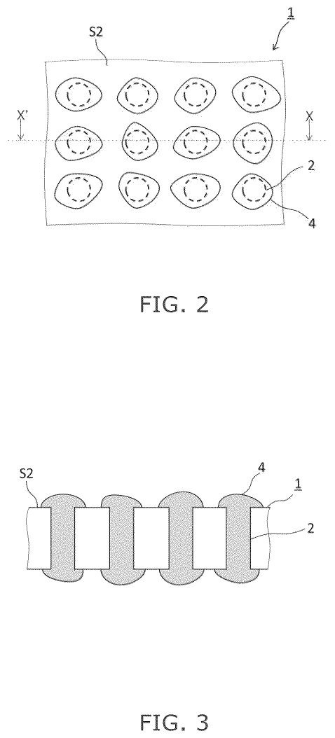

FIG. 2 is a front view of the discharge surface S2 of the printed wiring board 1 in the state of curing the curable resin composition 3 filled into each through-hole 2 in the printed wiring board 1 in which the plurality of through-holes 2 are opened at regular spacings. FIG. 3 is a cross-sectional view taken along the line X-X′ line of FIG. 2. As described above, the swellings 4 formed by discharging the curable resin composition 3 from the through-holes 2 are cured on an as-is basis on the discharge surface S2 of the printed wiring board 1. The shapes of the swellings 4 differ according to the corresponding through-holes 2. In other words, it can be considered that the principal surface reverse to the printing side, of the principal surfaces of the printed wiring board 1, includes each of cured product-coating regions 4 in which the principal surface S2 of the substrate is coated with the cured product of the curable resin composition 3 to cover the periphery of each of the through-holes 2.

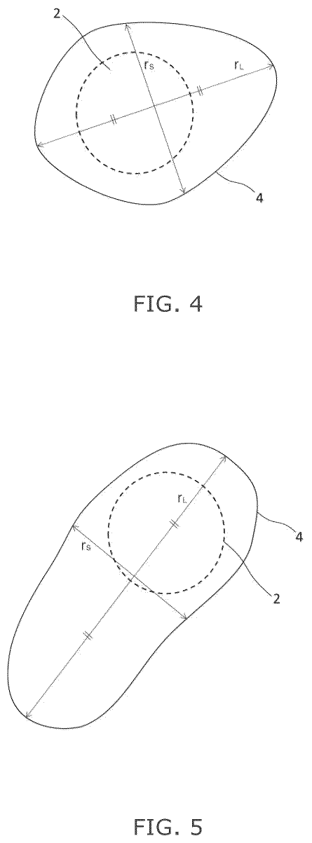

FIG. 4 is an enlarged view of any one of the through-holes 2 illustrated in FIG. 2. In other words, FIG. 4 is the enlarged view of the discharge surface S2 of the printed wiring board 1, viewed from the front. When the linear longest distance between the cured product-coating regions 4 described above is r_{L} (μm), and the linear longest distance of a line segment orthogonal to the line segments of r_{L} at a center of the line segment of r_{L} is r_{S} (μm), cured product-coating regions satisfying

$$1 \leq {r}_{L} / {r}_{S} \leq 1.5$$

are 50% or more of all the cured product-coating regions. Such a through-hole 2 has a generally circular shape when the through-hole 2 is viewed from the front in a case in which the through-hole 2 has a generally columnar shape. When such a cured product-coating region has a concentrically circular shape, r_{L}/r_{S} is 1. In contrast, r_{L}/r_{S} is 1.5 or more when such a cured product-coating region 4 has an irregular shape, particularly a shape extending in one direction, as illustrated in FIG. 5. In the present invention, each cured product-coating region 4 may have an optional shape, and cured product-coating regions satisfying 1≤r_{L}/r_{S}≤1.5 are set at 50% or more of all the cured product-coating regions, whereby the printed wiring board in which the through-holes are filled with the cured product of the curable resin composition, and which includes a smooth surface including no recess after polishing of the surface can be obtained.

In other words, with increasing the number of cured product-coating regions having shapes similar to the shapes (that is, generally circular shapes) of the openings of the through-holes, the probability of generation of recesses after polishing is decreased to enable formation of a smooth surface without any recesses when the unwanted portions of the swellings 4 protruding from the through-holes 2 in the surface is removed and flattened by the polishing. The reason for the above is unclear. When such a cured product-coating region has is a generally circular shape, the shape of the cured product-coating region in a thickness direction also tends to be a symmetric projection shape, and therefore, only the swelled portion having the projection shape is polished and smoothed in the case of the polishing. It can be presumed that when the shape (for example, an oval shape or the like) of a cured product-coating region is different from a circular shape, the shape of the cured product-coating region in the thickness direction is not a symmetric projection shape but an irregular shape, the thin portion of the cured product-coating region peels off or is scraped off as a lump in polishing, and a recess is generated. In particular, when the shape of a cured product-coating region in a thickness direction is not a symmetric projection shape but is eccentric, the position of the top of the projection shape deviates from the center of each through-hole, and therefore, a recess is prone to be generated on the through-hole. It is difficult to polish the thin portion of a cured product-coating region, multiple times of polishing are required for the portion, and therefore, the portion may be excessively polished, whereby a recess may be generated. In the present invention, “cured product-coating regions satisfying 1≤r_{L}/r_{S}≤1.5” mean the total number of portions satisfying 1≤r_{L}r_{S}≤1.5 in the individual cured product-coating regions 4 described above, and “all the cured product-coating regions” mean the total number of the individual cured product-coating regions 4 described above. When individual cured product-coating regions are connected and contiguous to each other between through-holes adjacent to each other, such a contiguous portion is not counted.

The above-described cured product-coating regions satisfying 1≤r_{L}/r_{S}1.5 are preferably 60% or more, more preferably 70% or more, of all the cured product-coating regions from the viewpoint of obtaining a printed wiring board having a smooth surface without any recess after polishing of the surface.

The composition and printing conditions (filling conditions) of the curable resin composition, the conditions of curing, and the like may be set as appropriate in order to form such cured product-coating regions as described above in the printed wiring board in which the through-holes are filled with the cured product of the curable resin composition. The composition of the curable resin composition is described in detail below.

### [Curable Resin]

The curable resin composition according to the present invention includes a curable resin which is a curable component. A thermosetting resin can be used without particular limitation as long as being able to be cured by heat. An epoxy resin can be preferably used as the thermosetting resin. The epoxy resin can be used without limitation as long as including two or more epoxy groups in a molecule. Examples thereof include bisphenol A type epoxy resins, bisphenol F type epoxy resins, hydrogenated bisphenol A type epoxy resins, brominated bisphenol A type epoxy resins, bisphenol S type epoxy resins, phenol novolac type epoxy resins, cresol novolac type epoxy resins, novolac type epoxy resins of bisphenol A, biphenyl type epoxy resins, naphthol type epoxy resins, naphthalene type epoxy resins, dicyclopentadiene type epoxy resins, triphenylmethane type epoxy resins, alicyclic epoxy resins, aliphatic chain epoxy resins, phosphorus-containing epoxy resins, anthracene type epoxy resins, norbornene type epoxy resins, adamantane type epoxy resins, fluorene type epoxy resins, aminophenol type epoxy resins, aminocresol type epoxy resins, and alkylphenol type epoxy resins. The epoxy resins described above may be used singly, or in combination of two or more kinds thereof.

Examples of the epoxy resins described above include solid, semisolid, and liquid epoxy resins in view of a form prior to curing. Such epoxy resins may be used singly, or in combination of two or more kinds thereof. A liquid state refers to the state of a liquid having flowability at 20° C., and a semisolid state refers to the state of a solid having no flowability at 20° C. and a liquid having flowability at 40° C.

Examples of the solid epoxy resins include: epoxidized products (trisphenol type epoxy resins) of condensates of phenols and aromatic aldehydes having phenolic hydroxyl groups, such as EPPN-502H (trisphenol epoxy resin) manufactured by Nippon Kayaku Co., Ltd.; dicyclopentadiene aralkyl type epoxy resins such as EPICLON HP-7200H (polyfunctional solid epoxy resin containing dicyclopentadiene skeleton) manufactured by DIC Corporation; novolac type epoxy resins such as EPICLON N660 and EPICLON N690 manufactured by DIC Corporation and EOCN-104S manufactured by Nippon Kayaku Co., Ltd.; phenol novolac type epoxy resins such as D.E.N. 431 manufactured by Dow Chemical Japan Ltd.; biphenyl type epoxy resins such as YX-4000 manufactured by Mitsubishi Chemical Corporation; phosphorus-containing epoxy resins such as TX0712 manufactured by NIPPON STEEL Chemical & Material Co., Ltd.; tris(2,3-epoxypropyl)isocyanurate such as TEPIC manufactured by Nissan Chemical Corporation; and bisphenol A type epoxy resins such as jER1001 manufactured by Mitsubishi Chemical Corporation.

Examples of the semisolid epoxy resins include: bisphenol A type epoxy resins such as EPICLON 860, EPICLON 900-IM, EPICLON EXA-4816, and EPICLON EXA-4822 manufactured by DIC Corporation, Epotohto YD-134 manufactured by NIPPON STEEL Chemical & Material Co., Ltd., jER834 and jER872 manufactured by Mitsubishi Chemical Corporation, and ELA-134 manufactured by SUMITOMO CHEMICAL COMPANY, LIMITED; and phenol novolac type epoxy resins such as EPICLON N-740 manufactured by DIC Corporation.

Examples of the liquid epoxy resins include ZX-1059 (mixture product of bisphenol A type epoxy resin and bisphenol F type epoxy resin) manufactured by NIPPON STEEL Chemical & Material Co., Ltd., jER828 (bisphenol A type epoxy resin) manufactured by Mitsubishi Chemical Corporation, jER807 and jER4004P (bisphenol F type epoxy resins) manufactured by Mitsubishi Chemical Corporation, R710 (bisphenol E type epoxy resin) manufactured by AIR WATER INC., TETRAD-X (aromatic amine type epoxy resin) manufactured by MITSUBISHI GAS CHEMICAL COMPANY, INC., jER630 (amino phenol type epoxy resin) manufactured by Mitsubishi Chemical Corporation, ED-509S (tert-butylphenylglycidylether) manufactured by ADEKA CORPORATION, EP-3300E (hydroxybenzophenone type liquid epoxy resin) manufactured by ADEKA CORPORATION, ELM-100 (para-aminophenol type liquid epoxy resin) manufactured by SUMITOMO CHEMICAL COMPANY, LIMITED, jER604 (glycidyl amine type epoxy resin) manufactured by Mitsubishi Chemical Corporation, Epotohto YH-434 (glycidyl amine type epoxy resin) manufactured by NIPPON STEEL Chemical & Material Co., Ltd., and SUMI-EPOXY ELM-120 manufactured by SUMITOMO CHEMICAL COMPANY, LIMITED.

The total solid content of the blended epoxy resin is preferably 5 to 70% by volume, more preferably 10 to 60% by volume, with respect to the total solid content of the curable resin composition.

The epoxy resin used in the present invention is preferably liquid rather than solid in consideration of the coating film formability of a curable resin composition, that is, coating properties such as printability. In particular, the viscosity of the epoxy resin is preferably 50 Pa·s or less, more preferably 20 Pa·s or less, and still more preferably 5 Pa·s or less. The viscosity herein refers to viscosity measured using a cone-plate type viscometer (TV-33H, rotor 3°×R9.7 or rotor 1°34′×R24, manufactured by Toki Sangyo Co., Ltd.) at 25±1° C. and a rotor rotation speed of 5.0 rpm for 30 seconds according to JIS Z8803:2011 “10 Viscosity Measurement Method by Cone-Plate Type Rotation Viscometer”.

### [Curing Agent]

The curable resin composition of the present invention includes a curing agent for curing the curable resin described above. Such curing agents can be used without particular limitation as long as having the effect of accelerating the reaction of curing an epoxy resin. Examples thereof include amines, imidazoles, polyfunctional phenols, acid anhydrides, isocyanates, and polymers including these functional groups. A plurality of such curing agents may be used as needed. Examples of amines include dicyandiamide and diaminodiphenyl methane. Examples of imidazoles include alkyl-substituted imidazoles and benzimidazole. An imidazole compound may be an imidazole latent curing agent such as an imidazole adduct form. Examples of polyfunctional phenols include hydroquinone, resorcinol, bisphenol A, and halogen compounds thereof, and novolac and resole resins which are condensates thereof with aldehydes. Examples of acid anhydrides include phthalic anhydride, hexahydrophthalic anhydride, methylnadic anhydride, and benzophenonetetracarboxylic acid. Examples of isocyanates include tolylene diisocyanate and isophorone diisocyanate, and such isocyanates masked with phenols may also be used. These curing agents may be used singly, or in combination of two or more kinds thereof.

Aliphatic polyamines and alicyclic polyamines are preferably used as amines. Examples of the aliphatic polyamines include: C₂-C₆ alkylene diamines such as ethylene diamine and propylene diamine; C₂-C₆ polyalkylene polyamines such as diethylene triamine and triethylene triamine; and C₈-C₁₅ aliphatic polyamines containing aromatic rings such as xylylene diamine. Examples of the commercially available products of modified aliphatic polyamines include: Fujicure FXE-1000, Fujicure FXR-1020, Fujicure FXR-1030, Fujicure FXR-1080, and Fujicure FXR-1090M2 (manufactured by T&K TOKA CO., LTD.); and ANCAMINE 2089K, SUNMIDE P-117, SUNMIDE X-4150, ANCAMINE 2422, SURWET R, SUNMIDE TX-3000, and SUNMIDE A-100 (manufactured by Evonik Japan Co., Ltd.).

Examples of alicyclic polyamines include isophoronediamine, 1,3-bis(aminomethyl)cyclohexane, bis(4-aminocyclohexyl)methane, norbornene diamine, 1,2-diaminocyclohexane, and Laromin. Examples of the commercially available products of modified alicyclic polyamines include: ANCAMINE 1618, ANCAMINE 2074, ANCAMINE 2596, ANCAMINE 2199, SUNMIDE IM-544, SUNMIDE 1-544, ANCAMINE 2075, ANCAMINE 2280, ANCAMINE 1934, and ANCAMINE 2228 (manufactured by Evonik Japan Co., Ltd.); DAITOCURAR F-5197 and DAITOCURAR B-1616 (manufactured by DAITO SANGYO CO., LTD.); Fujicure FXD-821 and Fujicure 4233 (manufactured by T&K TOKA CO., LTD.); jER Cure 113 (manufactured by Mitsubishi Chemical Corporation); and Laromin C-260 (manufactured by BASF Japan Ltd.). In addition, examples of polyamine type curing agents include EH-5015S (manufactured by ADEKA CORPORATION).

An imidazole refers to, for example, a reactant of epoxy resin and imidazole, or the like. Examples thereof include 2-methylimidazole, 4-methyl-2-ethylimidazole, 2-phenylimidazole, 4-methyl-2-phenylimidazole, 1-benzyl-2-methylimidazole, 2-ethylimidazole, 2-isopropylimidazole, 1-cyanoethyl-2-methylimidazole, 1-cyanoethyl-2-ethyl-4-methylimidazole, and 1-cyanoethyl-2-undecylimidazole. Examples of the commercially available products of imidazole compounds include imidazoles such as 2E4MZ, C11Z, C17Z, and 2PZ, AZINE (azine) compounds of imidazoles such as 2MZ-A and 2E4MZ-A, isocyanurates of imidazoles such as 2MZ-OK and 2PZ—OK, and imidazole hydroxymethyl compounds such as 2PHZ and 2P4MHZ (all of which are manufactured by SHIKOKU CHEMICALS CORPORATION). Examples of the commercially available products of imidazole type latent curing agents include CUREDUCT P-0505 (manufactured by SHIKOKU CHEMICALS CORPORATION).

When the total solid content of the curable resin is set at 100 parts by mass, the amount of the blended curing agent described above is preferably 1 to 100 parts by mass, more preferably 2 to 50 parts by mass, and particularly more preferably 5 to 20 parts by mass. In particular, in a case in which the amount of the blended curing agent is 5 parts by mass or more, a decrease in the precure speed of the resin composition is commonly prevented, therefore, there is in sufficient curing of the composition in the deep portion of a hole. As a result, cracking can be prevented from occurring, and therefore, the case is preferred. In a case in which the amount of the blended curing agent is 50 parts by mass or less, storage stability is favorable, the excessively high precure speed of the resin composition is commonly prevented to inhibit voids from remaining in the cured product. Therefore, the case is preferred.

### [Inorganic Filler]

The curable resin composition according to the present invention includes an inorganic filler, Stress relaxation due to cure shrinkage in the case of filling a curable resin composition into through-bores such as through-holes in a printed wiring board and then curing the curable resin composition, and a linear expansion coefficient can be adjusted by blending the inorganic filler. A known inorganic filler that is used in a common resin composition can be used as the inorganic filler. Specific examples thereof include: nonmetal fillers such as silica, barium sulfate, calcium carbonate, silicon nitride, aluminum nitride, boron nitride, alumina, magnesium oxide, aluminum hydroxide, magnesium hydroxide, titanium oxide, mica, talc, and organic bentonite; and metal fillers such as copper, gold, silver, palladium, and silicone. These inorganic fillers may be used singly, or in combination of two or more kinds thereof.

Among these inorganic fillers, calcium carbonate, silica, barium sulfate, and aluminum oxide excellent in low moisture-absorption characteristics and low volumetric expansion characteristics are preferably used, and especially, silica and calcium carbonate are more preferably used. Silica may be amorphous or crystalline, and a mixture of amorphous silica and crystalline silica is also acceptable. Amorphous (fused) silica is particularly preferred. Calcium carbonate may be natural ground calcium carbonate or synthetic precipitated calcium carbonate.

A magnetic filler can also be used as the inorganic filler. The inclusion of the magnetic filler enables a noise electromagnetic wave in a near electromagnetic field to be suppressed or absorbed, and therefore enables formation of an electronic component excellent in a characteristic such as noise suppression even when a plurality of circuit elements are mounted. Moreover, the magnetic filler can be preferably used as an insulation material of an inductor element for a high frequency, requiring high relative permeability at 1 MHz to 200 MHz. In particular, the inclusion of the magnetic filler in the curable resin composition that is filled into the through-holes enables characteristics for an inductor to be imparted into the through-holes, resulting in possible contribution to compactization of the substrate.

The magnetic filler can be used without particular limitation, and examples thereof include: nonconductive magnetic materials such as spinel-type ferrites such as Mg—Zn-based ferrite, Mn—Zn-based ferrite, Mn—Mg-based ferrite, Mn-based ferrite, Cu—Zn-based ferrite, Mg—Mn—Sr-based ferrite, Ni—Zn—Cu-based ferrite, and Ni—Zn-based ferrite, hexagonal crystal type ferrites such as Ba—Zn-based ferrite, Ba—Mg-based ferrite, Ba—Ni-based ferrite, Ba—Co-based ferrite, and Ba—Ni—Co-based ferrite, and garnet-type ferrites such as magnetite and Y-based ferrite; and conductive magnetic materials such as Fe alloys, Ni alloys, and high-Si-based alloys such as pure iron powder, Fe—Si-based alloy powder, Fe—Si—Al-based alloy powder, Ni powder, Fe—Ni-based alloy powder, Fe—Ni—Mo-based alloy powder, Fe—Ni—Mo—Cu-based alloy powder, Fe—Co-based alloy powder, Fe—Ni—Co-based alloy powder, Fe—Cr-based alloy powder, Fe—Cr—Si-based alloy powder, Fe—Ni—Cr-based alloy powder, and Fe—Cr—Al-based alloy powder, and amorphous alloys such as Fe-group amorphous alloys and Co-group amorphous alloys.

A commercially available magnetic filler can be used as the magnetic filler. Specific examples of the commercially available magnetic filler include: “AW2-08PF3FG” manufactured by EPSON ATMIX Corporation; “KNI-106” and “KNI-109” manufactured by JFE Chemical Corporation; “BSN-125”, “BSN-714” and “BSN-828” manufactured by TODA KOGYO CORP.; and “M10S”, “M03S”, “NZ03S”, “E03S”, “M001”, and “E001” manufactured by Powdertech Co., Ltd.. Such magnetic powders may be used singly, or in combination of two or more kinds thereof.

The shape of the inorganic filler is not particularly limited, and examples thereof include spherical, acicular, plate, scaly, hollow, indeterminate, hexagonal, cubic, and flaky shapes. A spherical shape is preferred from the viewpoint of the high blending of the inorganic filler.

The average particle diameter of the inorganic filler is preferably 0.1 μm to 20 μm, more preferably 0.1 μm to 15 μm, still more preferably 0.1 μm to 10 μm in consideration of dispersibility in the inorganic filler, filling properties into holes, and smoothness in the case of forming a wiring layer on a filled portion. An average particle diameter means a particle diameter corresponding to a volume accumulation of 50% (D50% by volume) including not only the particle diameters of primary particles but also the particle diameters of secondary particles (aggregate) and can determined as a median diameter (D50, on a volumetric basis) in a cumulative distribution from the measured value of a particle size distribution by a laser diffraction/scattering method using a laser diffraction scattering type particle size distribution measurement apparatus (MT3300EX manufactured by MicrotracBEL Corp.). The average particle diameter of an inorganic filler refers to a value obtained by measuring a powder form prior to preparation (pre-stirring and kneading) of a resin composition, as described above.

The inorganic filler described above may be subjected to surface treatment. For example, the surface of the magnetic powder can be treated with a coupling agent or the like having a curable reactive group as an organic group. A coupling agent based on silane, titanate, aluminate, zircoaluminate, or the like can be used as the coupling agent. Examples of such silane-based coupling agents include vinyltrimethoxysilane, vinyltriethoxysilane, N-(2-aminomethyl)-3-aminopropylmethyldimethoxysilane, N-(2-aminoethyl)-3-aminopropyltrimethoxysilane, 3-aminopropyltriethoxysilane, 3-anilinopropyltrimethoxysilane, 3-glycidoxypropyltrimethoxysilane, 3-glycidoxypropylmethyldimethoxysilane, 2-(3,4-epoxycyclohexyl)ethyltrimethoxysilane, 3-methacryloxypropyltrimethoxysilane, and 3-mercaptopropyltrimethoxysilane, which may be used singly, or in combination. Such silane-based coupling agents are preferably adsorbed or fixed by reaction on the surface of the inorganic filler in advance.

A thermosetting reactive group is preferred as the curable reactive group. Examples of the thermosetting reactive group include a hydroxyl group, a carboxyl group, an isocyanate group, an amino group, an imino group, an epoxy group, an oxetanyl group, a mercapto group, a methoxymethyl group, a methoxyethyl group, an ethoxymethyl group, an ethoxyethyl group, and an oxazoline group. Among them, at least any one of an amino group and an epoxy group is preferred.

The inorganic filler subjected to surface treatment may be contained in the state of being surface-treated in a curable resin composition, the curable resin composition may be blended separately with the inorganic filler and a surface treatment agent to surface-treat the inorganic filler in the curable resin composition, and it is preferable to blend the inorganic filler surface-treated in advance. The deterioration of cracking resistance and the like due to the surface treatment agent that can remain in the case of the separate blending and has not been consumed in the surface treatment can be prevented by blending the inorganic filler surface-treated in advance. In the case of surface treatment in advance, it is preferable to blend a predispersion liquid in which an inorganic filler is predispersed in a solvent component or a resin component, and it is more preferable to predisperse an inorganic filler subjected to the surface treatment in a solvent component or a resin component to blended a composition with the predispersion liquid, or to sufficiently surface-treat an inorganic filler that has not been surface-treated in the case of predispersing the inorganic filler in a solvent component or a resin component, followed by blending a curable resin composition with the predispersion liquid.

A larger amount of the inorganic filler allows a cured product having a more favorable magnetic property to be obtained. However, the inorganic filler is preferably contained at a ratio of 40 to 90% by mass, more preferably contained at a ratio of 50 to 90% by mass, with respect to the total solid content of the curable resin composition, from the viewpoint of balancing and insulation property and a filling property into a hole having a small diameter or a narrow gap.

### [Other Components]

In addition, the curable resin composition of the present invention may be optionally blended with an oxazine compound having an oxazine ring, obtained by reaction of a phenol compound, formalin, and primary amine. The containment of the oxazine compound can facilitate roughening of a cured product by an aqueous potassium permanganate solution or the like to improve the strength of peeling from plating in the case of electroless plating on the cured product formed after curing of a curable resin composition filled into the holes of a printed wiring board.

In addition, a known coloring agent such as phthalocyanine blue, phthalocyanine green, iodine green, disazo yellow, crystal violet, titanium oxide, carbon black, or naphthalene black, used in usual resist ink for screen printing, may be added.

Moreover, a known thermal polymerization inhibitor such as hydroquinone, hydroquinone monomethyl ether, tert-butylcatechol, pyrogallol, or phenothiazine for imparting storage stability in storage, or a known thickener or thixotropy agent such as clay, kaolin, or montmorillonite for adjusting viscosity or the like can be added. In addition, a known additive such as an antifoaming agent based on silicone, fluorine, polymer, or the like, a leveling agent, or an adhesiveness-imparting agent based on thiazole, triazole, or the like can be blended.

A diluting solvent is not necessarily used in the curable resin composition of the present invention. However, in order to adjust the viscosity of the curable resin composition, a diluting solvent may be added to such a degree that any void is not generated.

Examples of the diluting solvent include: ketones such as methyl ethyl ketone and cyclohexanone; aromatic hydrocarbons such as toluene, xylene, and tetramethylbenzene; glycol ethers such as methyl cellosolve, butyl cellosolve, methyl carbitol, butyl carbitol, propylene glycol monomethyl ether, dipropylene glycol monoethyl ether, and triethylene glycol monoethyl ether; esters such as ethyl acetate, butyl acetate, and products obtained by acetic acid esterification of the glycol ethers described above; alcohols such as ethanol, propanol, ethylene glycol, and propylene glycol; aliphatic hydrocarbons such as octane and decane; and petroleum-based solvents such as petroleum ether, petroleum naphtha, hydrogenated petroleum naphtha, and solvent naphtha.

The viscosity of the curable resin composition of the present invention at 25±1° C. is preferably in a range of 100 to 1000 dPa·s, more preferably 200 to 800 dPa·s, and particularly preferably 200 to 600 dPa·s. Such a range can facilitate filling into the holes and enables favorable filling into the recesses and the through-bores without generation of voids and the like. The viscosity herein refers to viscosity measured using a cone-plate type viscometer (TV-33H, rotor 3°×R9.7, manufactured by Toki Sangyo Co., Ltd.) at 25° and a rotor rotation speed of 5.0 rpm for 30 seconds according to JIS Z8803:2011 “10 Viscosity Measurement Method by Cone-Plate Type Rotation Viscometer”.

The curable resin composition is cured to form the cured product by heating the multilayer printed wiring board in which the holes and recesses are filled with the curable resin composition, for example, at 80 to 160° C. for around 30 to 180 minutes. The curable resin composition may be cured at two stages from the viewpoint of easily removing the unnecessary portion, protruding from a surface of the substrate after the filling, of the cured product by physical polishing. In other words, the curable resin composition can be precured at a lower temperature, and then mainly cured (finally cured). For conditions for the precuring, heating at 80 to 130° C. for around 30 to 180 minutes is preferred. Since the hardness of the cured product that has been precured is relatively low, the unnecessary portion protruding from the substrate surface can be easily removed by physical polishing, to form a flat surface. Then, the composition is heated and mainly cured. For conditions for the main curing, heating at 140 to 180° C. for around 30 to 180 minutes is preferred.

The curing can be performed using a circulating type hot-air drying oven, an IR furnace, a hot plate, a convection oven, or the like (a method for countercurrent contact with hot blast in a drying machine using an instrument including a heat source with an air heating system by vapor, and a system for spraying on a product to be cured through a nozzle) in both of the precuring and the main curing. Among them, a circulating type hot-air drying oven is particularly preferred. In such a case, the cured product is hardly expanded and shrunk due to low expansibility to form a final cured product that has favorable dimensional stability and is excellent in low water vapor absorption, adhesiveness, electrical insulation properties, and the like. The hardness of the precured product can be controlled by changing the heating time and heating temperature for the precuring.

The curable resin composition is cured as described above, the unwanted portion (swelling portion) of the cured product protruding from the surface of the printed wiring board is then removed and flattened by a known physical polishing method, and a wiring layer on the surface is then patterned to have a predetermined pattern to form a predetermined circuit pattern. As needed, the surface of the cured product may be roughened by an aqueous potassium permanganate solution or the like, followed by forming a wiring layer on the cured product by electroless plating or the like.

### Examples

The present invention will now be described in more detail with reference to Examples. However, the present invention is not limited to these Examples. All the following terms “part(s)” and “%” are based on mass, unless otherwise specified.

### <Preparation of Curable Resin Composition>

Various components set forth in the following Table 1 were mixed at corresponding rates (part(s) by mass) set forth in the table, and homogeneously mixed and dispersed by three rolls to prepare each curable resin composition in Examples 1 to 6 and Comparative Examples 1 to 3.

In Table 1, *1 to *16 represent the following components.
*1: Bisphenol A type epoxy resin (jER-828, manufactured by Mitsubishi Chemical Corporation)
*2: Meta-xylenediamine type epoxy resin (TETRAD-X, manufactured by MITSUBISHI GAS CHEMICAL COMPANY, INC.)
*3: Triglycidyl-p-aminophenol resin (jER-630, manufactured by Mitsubishi Chemical Corporation)
*4: 4-tert-butylphenylglycidylether (ED-509S, manufactured by ADEKA CORPORATION)
*5: Imidazole-based curing agent (2MZA-PW, manufactured by SHIKOKU CHEMICALS CORPORATION)
*6: Silica particles (FE920A-SQ, manufactured by ADMATECHS COMPANY LIMITED, average particle diameter of 5.6 μm)
*7: Silica particles (SC6500-SQ, manufactured by ADMATECHS COMPANY LIMITED, average particle diameter of 2.1 μm)
*8: Silica particles (NQ1110H, manufactured by NOVORAY, average particle diameter of 6.2 μm)
*9: Calcium carbonate particles (SOFTON 3200, manufactured by BIHOKU FUNKA KOGYO CO., LTD., average particle diameter of 3.2 μm)
*10: Calcium carbonate particles (SOFTON 1800, manufactured by BIHOKU FUNKA KOGYO CO., LTD., average particle diameter of 1.8 μm)
*11: Magnetic filler particles (M10S, manufactured by Powdertech Co., Ltd., average particle diameter of 4.0 μm)
*12: Titanium oxide particles (TIPAQUE CR-58, manufactured by ISHIHARA SANGYO KAISHA, LTD., average particle diameter of 0.3 μm)
*13: Silane coupling agent (KBM-403, manufactured by Shin-Etsu Chemical Co., Ltd.)
*14: Antifoaming agent (KS-66, manufactured by Shin-Etsu Chemical Co., Ltd.)
*15: Bentonite (ORBEN M, manufactured by Shiraishi Kogyo Kaisha, Ltd.)
*16: Wet dispersant (DISPERBYK-111, BYK JAPAN KK)

### <Production of Printed Wiring Board>

The curable resin composition is defoamed using an agitation defoaming machine (ARE-310, manufactured by THINKY CORPORATION) under conditions of 2000 rpm in MIXING mode for 8 minutes and 2200 rpm in DEFORM mode for 2 minutes. Only in Example 3, the curable resin composition is defoamed using the agitation defoaming machine (ARE-310, manufactured by THINKY CORPORATION) under conditions of 1800 rpm in MIXING mode for 2 minutes and 1800 rpm in DEFORM mode for 1 minute.

Then, a glass epoxy substrate (FR-4 substrate: a glass epoxy substrate of 150 mm×290 mm×1.6 mm in thickness/0.12 mm in through-hole diameter (after the plating)/1 mm in pitch, in which a conductor layer was formed by panel plating, and which had had through-holes) was acid-washed, and then dried at 150° C. for 15 minutes by a hot blast circulating type drier (DF612 manufactured by Yamato Scientific Co., Ltd.).

Subsequently, the curable resin composition in each of Examples and Comparative Examples was filled from one surface of the substrate into the through-holes by a screen printing method using a semiautomatic printer (SSA-PC660A, manufactured by SERIA CORPORATION) under the following printing conditions. When the curable resin composition was filled, the curable resin composition was discharged from through-holes in a side reverse to the printed side, the amount of the filled curable resin composition was adjusted to prevent curable resin compositions discharged from through-holes adjacent to each other from coming into contact with each other, and the amount of an injected curable resin composition per through-hole was set at 0.04 & 0.01 mm³.

Then, the curable resin composition was filled, the substrate was then mounted on a substrate rack so that the principal surface of the substrate was at an angle of 90°±10° with respect to a mounting surface, and a temperature was increased from ordinary temperature to 130° C. for 10 minutes, kept at 130° C. for 45 minutes, then increased from 130° C. to 150° C. for 10 minutes, and kept at 150° C. for 60 minutes to cure the curable resin composition to produce an evaluation substrate.

### (Printing Conditions)

Squeegee: squeegee thickness of 20 mm, flat squeegee (hardness of 700)
Screen plate: PET 200 mesh bias plate, opening diameter of 600 μm (dot pattern), emulsion thickness of 30 μm
Printing pressure: 60 kg
Squeegee speed: 5 mm/see
Squeegee angle: 93° (attack angle of 3°)
Screen plate clearance: 1.5 mm
Dent amount (distance at which a squeegee is dented from a position at which a distance between the squeegee and a substrate is zero in the case of printing): 7 mm
   <Calculation of Rate of 1≤r_{L}/r_{S}≤1.5>

The principal surface, reverse to the printing side, of the principal surfaces of the evaluation substrate produced as described above was observed using a microscope (VHX-6000, manufactured by KEYENCE CORPORATION) at a 200-fold magnification. The linear longest distance r_{L}(μm) of a cured product-coating region in which the cured product was coated on the principal surface of the evaluation substrate to cover the periphery of each through-hole, and the linear longest distance of a line segment orthogonal to the line segment of the r_{L} at a center of the line segment of r_{L} were measured to calculate r_{L}/r_{S}.

The values of rd_{L}/r_{S} of all the cured product-coating regions were calculated, and a rate of cured product-coating regions within a range of 1≤r_{L}/r_{S}≤1.5 was calculated.

<Smoothness after Polishing>

The principal surface reverse to the printing side of the evaluation substrate was physically polished by a buffing machine in which High Cut Buff 19 (SFBR—#320 manufactured by SUMITOMO 3M LIMITED) was one-axis-set on one surface until resin was completely removed. Then, the polished surface was observed from a front direction using a laser microscope (VK-X100, manufactured by KEYENCE CORPORATION) at a 200-fold magnification, it was confirmed whether recesses were present in the surfaces of the through-holes filled with the cured product, and a distance from the surface of the glass epoxy substrate to the greatest recess depth was measured in a shape measurement mode. The smoothness after the polishing was evaluated based on the following evaluation criteria.
Excellent: Recess depth of 5 μm or less
Good: Recess depth of more than 5 μm and 10 μm or less
Poor: Recess depth of more than 10 μm
The evaluation results are as set forth in the following Table 1.

### <Magnetic Properties>

Magnetic properties were evaluated to confirm characteristics such as noise suppression. A curable resin composition cured by applying each curable resin composition in Examples and Comparative Examples to copper foil by an applicator with a gap of 100 μm and heating the copper foil by a circulating type hot-air drying oven (DF610 manufactured by Yamato Scientific Co., Ltd.) at 150° C. for 30 minutes was cut into a size of 1 cm×3 cm to form an evaluation substrate. Then, each of the complex magnetic permeability (μ), real part (μ′), imaginary part (μ″), and imaginary number (j) of each evaluation substrate at a temperature of 25° C. and at 10 MHz to 1 GHz was measured using an ENA network analyzer (E5071C manufactured by Keysight). The relationship of each item is represented by μ=μ′=jμ″. The mean value of the values of 11 points at around 100 MHz was regarded as an index. In the case of μ′>1.0, magnetism may be considered to be present.
Present: μ′>1.0
Absent: μ′=1.0

The evaluation results are as set forth in the following Table 1.

TABLE 1

| | | Example | | | | | | | Comparative Example | | |
|---|---|---|---|---|---|---|---|---|---|---|---|
| Composition | | 1 | 2 | 3 | 4 | 5 | 6 | 7 | 1 | 2 | 3 |
| Curable | jER-828*¹ | 65 | 65 | 50 | — | 5 | 65 | 65 | 60 | 65 | 65 |
| resin | TETRAD-X*² | 15 | 10 | — | 100 | 80 | 10 | 10 | 15 | 10 | 15 |
| | jER-630*³ | 35 | 35 | 50 | — | 20 | 35 | 35 | 35 | 35 | 35 |
| | ED-509S*⁴ | 5 | 4 | 5 | — | 3 | 4 | 4 | 4 | 4 | 5 |
| Curing agent | 2MZA-PW*⁵ | 8 | 8 | 8 | 6 | 8 | 8 | 8 | 8 | 8 | 8 |
| Inorganic | FE-920A-SQ*⁶ | 160 | 130 | — | 130 | — | 100 | 85 | 280 | — | 100 |
| filler | SC6500-SQ*⁷ | 120 | 110 | — | — | — | 110 | 110 | — | 110 | 180 |
| | NQ1110H*⁸ | — | 40 | — | — | — | 70 | 85 | — | 170 | — |
| | SOFTON 3200*⁹ | 5 | 5 | — | — | 5 | 5 | 5 | — | 5 | 5 |
| | SOFTON 1800*¹⁰ | — | — | — | 20 | 150 | — | — | 30 | — | — |
| | M10S*¹¹ | — | — | 700 | — | — | — | — | — | — | — |
| | TIPAQUE CR-58*¹² | — | — | 50 | — | — | — | — | — | — | — |
| Other | KBM-403*¹³ | 5 | 4 | — | — | — | 4 | 4 | 5 | 4 | 5 |
| components | KS-66*¹⁴ | 0.1 | 0.1 | 1 | 1 | 0.5 | 0.1 | 0.1 | — | 0.1 | 0.1 |
| | ORBEN M*¹⁵ | 2 | 1 | 0.5 | 4 | 0.1 | 1 | 1 | 1 | 1 | 2 |
| | DISPERBYK-111*¹⁶ | — | — | 3 | — | — | — | — | — | — | — |
| Content of inorganic filler | | 68 | 69 | 86 | 57 | 57 | 69 | 69 | 71 | 69 | 68 |
| (% by mass) | | | | | | | | | | | |
| Viscosity of curable resin | | 550 | 550 | 400 | 500 | 350 | 550 | 500 | 550 | 500 | 500 |
| composition (dpa · s) | | | | | | | | | | | |
| Evaluation | Rate (%) of 1 ≤ | 100 | 90 | 90 | 100 | 100 | 70 | 50 | 30 | 40 | 30 |
| | r_{L}/r_{S} ≤ 1.5 | | | | | | | | | | |
| | Smoothness | Excellent | Excellent | Excellent | Excellent | Excellent | Good | Good | Poor | Poor | Poor |
| | after polishing | | | | | | | | | | |
| | Magnetic properties | Absent | Absent | Present | Absent | Absent | Absent | Absent | Absent | Absent | Absent |

As shown the evaluation results in Table 1, it is found that the curable resin compositions (Examples 1 to 7) in which cured product-coating regions satisfying 1≤r_{L}/r_{S}≤1.5 were 50% or more with respect to the total cured product-coating regions resulted in small and smooth recesses on the polished surfaces of the through-holes filled with the cured products.

In contrast, it is found that the curable resin compositions (Comparative Examples 1 to 3) in which cured product-coating regions satisfying 1≤r_{L}/r_{S}≤1.5 were more than 50% with respect to the total cured product-coating regions resulted in large recesses on the polished surfaces of the through-holes filled with the cured products.

The invention claimed is:

1. A curable resin composition comprising a curable resin, a curing agent, and an inorganic filler, wherein
when the curable resin composition is filled from one principal surface side of a printed wiring board having a thickness of 1.6 mm, in which a plurality of through-holes comprising a wall surface subjected to plating treatment and having an inner diameter of 0.12 mm and a generally columnar shape are evenly spaced 1 mm apart in a substrate comprising a surface subjected to plating treatment and having a total thickness of 1.6 mm, into the through-holes, followed by curing the curable resin composition,
in a case in which a principal surface reverse to the principal surface side from which the curable resin composition is filled, of principal surfaces of the printed wiring board, is viewed from a front, the principal surface composes cured product-coating regions in which the principal surface of the substrate is coated with a cured product of the curable resin composition to cover a periphery of each of the through-holes, and
when a linear longest distance of each of the cured product-coating regions is r_{L} (μm), and a linear longest distance of a line segment orthogonal to the of line segment of the n, at a center of the line segment r_{L} of is r_{S}(μm),
cured product-coating regions satisfying
$$1 \leq {r}_{L} / {r}_{S} \leq 1.5$$
are 50% or more of all the cured product-coating regions.

2: The curable resin composition according to claim 1, wherein the inorganic filler is comprised at a ratio of 40 to 90% by mass with respect to a total solid content of the curable resin composition.

3. The curable resin composition according to claim 1, wherein an average particle diameter of the inorganic filler is 0.1 to 20 μm.

4. The curable resin composition according to claim 1, wherein the inorganic filler comprises a magnetic filler.

5: A method of producing a printed wiring board using the curable resin composition according to claim 1, the method comprising:
preparing a printed wiring board in which a plurality of through-holes having a generally columnar shape are disposed;
filling the curable resin composition from one principal surface side of the printed wiring board into the through-holes by printing; and
curing the filled curable resin composition,
wherein
when the curable resin composition is filled, the curable resin composition is discharged from through-holes in a principal surface reverse to the printed side, of principal surfaces of the printed wiring board, and an amount of the filled curable resin composition is adjusted to prevent curable resin compositions discharged from through-holes adjacent to each other from coming into contact with each other.

6: The method according to claim 5, further comprising polishing the principal surface reverse to the printed side, of the principal surfaces of the printed wiring board, after curing of the filled curable resin composition.
